(19) United States
(12) Patent Application Publication
(10) Pub. No.: US 2026/0076177 A1
(43) Pub. Date: Mar. 12, 2026

(54) SEMICONDUCTOR DEVICE CAPABLE OF PREVENTING DAMAGES CAUSED BY OXIDE CRACKING, AND METHOD FOR MANUFACTURING THE SAME

(71) Applicant: TAIWAN SEMICONDUCTOR MANUFACTURING COMPANY, LTD., Hsinchu (TW)

(72) Inventors: Hsin-Chi CHEN, Hsinchu (TW); S.H. CHANG, Hsinchu (TW); Wei Kai SHIH, Hsinchu (TW); Kuo-Lung TZENG, Hsinchu (TW)

(73) Assignee: TAIWAN SEMICONDUCTOR MANUFACTURING COMPANY, LTD., Hsinchu (TW)

(21) Appl. No.: 18/830,363

(22) Filed: Sep. 10, 2024

(51) Int. Cl. H01L 23/532; H01L 21/02; H01L 21/768; H01L 23/528

(52) U.S. Cl. CPC H10W 20/48; H10P 14/69433; H10W 20/077; H10W 20/435

(57) ABSTRACT

A semiconductor device includes a plurality of conductive lines, a protection layer and an isolation layer. The conductive lines are spaced apart from each other. The protection layer conformally covers the conductive lines. The isolation layer covers the protection layer. Ability of the protection layer to endure stress is better than ability of the isolation layer to endure stress.

### BACKGROUND

In semiconductor devices, oxides are used to electrically isolate metal lines. However, oxides are prone to cracking after prolonged use. This may damage the metal lines, and result in abnormal operation of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are schematic sectional views of a semiconductor device in accordance with some embodiments.

FIG. 3 is a schematic sectional view of a semiconductor device in accordance with some embodiments.

FIG. 4 is a plot illustrating an atomic percent of silicon atoms in a protection layer of the semiconductor device of FIGS. 1 and 2 in accordance with some embodiments.

FIG. 5 is a plot illustrating an atomic percent of silicon atoms in a protection layer of the semiconductor device of FIGS. 1 and 2 in accordance with some embodiments.

FIG. 6 is a schematic sectional view of a semiconductor device in accordance with some embodiments.

FIG. 7 is a schematic sectional view of a semiconductor device in accordance with some embodiments, illustrating a crack formed in an isolation layer is blocked by a protection layer.

FIG. 8 is a flow chart illustrating a method for manufacturing a semiconductor device in accordance with some embodiments.

FIGS. 9 to 15 are schematic sectional views illustrating intermediate stages of a method for manufacturing a semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

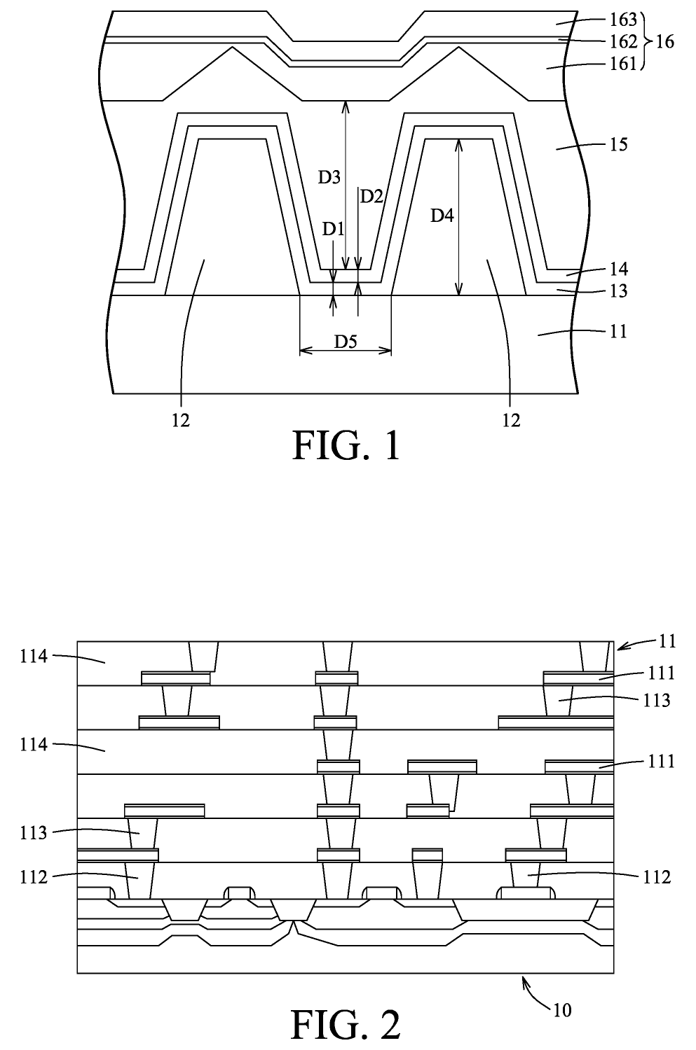

FIGS. 1 and 2 are schematic sectional views of a semiconductor device in accordance with some embodiments. Referring to FIGS. 1 and 2, the semiconductor device includes a substrate 10, an interconnect structure 11, a plurality of conductive lines 12, a capping layer 13, a protection layer 14, an isolation layer 15 and a passivation layer 16. The substrate 10 includes at least a plurality of transistors (e.g., planar field effect transistors (planar FETs), three-dimensional field effect transistors (3D FETs) such as fin field effect transistors (FinFETs), or the like) (not labeled). The interconnect structure 11 includes a plurality of metal lines 111, a plurality of conductive contacts 112, a plurality of conductive vias 113 and a plurality of inter-metal dielectric layers 114. The conductive lines 12 are disposed on the interconnect structure 11, and are spaced apart from each other. The conductive lines 12 cooperate with the metal lines 111, the conductive contacts 112 and the conductive vias 114 of the interconnect structure 11 to connect the transistors of the substrate 10 in a predetermined way, so the semiconductor device can perform predetermined operations. The capping layer 13 is disposed on the conductive lines 12 and the interconnect structure 11, and conformally covers top and side surfaces of each of the conductive lines 12, and portions of a top surface of the interconnect structure 11 that are not covered by the conductive lines 12. The protection layer 14 is disposed on the capping layer 13, and conformally covers an upper surface of the capping layer 13. The isolation layer 15 is disposed on the protection layer 14, covers an upper surface of the protection layer 14, and includes a plurality of downward protrusions that separate the conductive lines 12. The passivation layer 16 is disposed on the isolation layer 15, and covers an upper surface of the isolation layer 15. Adhesion of the capping layer 13 to the conductive lines 12 would be better than adhesion of the protection layer 14 to the conductive lines 12 if the capping layer 13 were to be omitted. Additionally, adhesion of the capping layer 13 to the protection layer 14 would also be better than the adhesion of the protection layer 14 to the conductive lines 12. Therefore, since the capping layer 13 has good adhesion to the conductive lines 12 and to the protection layer 14, the capping layer 13 is suitably disposed between the conductive lines 12 and the protection layer 14. Ability of the protection layer 14 to endure stress is better than ability of the isolation layer 15 to endure stress.

In some embodiments, the conductive lines 12 may be made of a conductive material, such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), gold (Au), aluminum (Al), or alloys thereof. Other suitable materials are within the contemplated scope of the present disclosure.

In some embodiments, the conductive lines 12 may be formed in a top metal layer of the semiconductor device as shown in FIGS. 1 and 2. However, in some other embodiments, the conductive lines 12 may be formed in a metal layer of the semiconductor device that is lower than the top metal layer of the semiconductor device, and the passivation layer 16 may be omitted.

The capping layer 13 is configured to improve the adhesion between the conductive lines 12 and the protection layer 14. In some embodiments, the capping layer 13 may be made of an oxide that contains silicon (Si) atoms (e.g., silicon oxide or the like). Other suitable materials are within the contemplated scope of the present disclosure. In some embodiments, an atomic percent of the silicon (Si) atoms in the capping layer 13 may be larger than or equal to about 15%. When the atomic percent of the silicon (Si) atoms in the capping layer 13 is smaller than about 15%, the adhesion of the capping layer 13 to the conductive lines 12 and the adhesion of the capping layer 13 to the protection layer 14 may be poor. It should be noted that the atomic percent of the silicon (Si) atoms in the capping layer 13 should not be made too large in order to retain the electrical isolation effect provided by the capping layer 13. In some embodiments, the atomic percent of the silicon (Si) atoms in the capping layer 13 may be smaller than or equal to about 30%

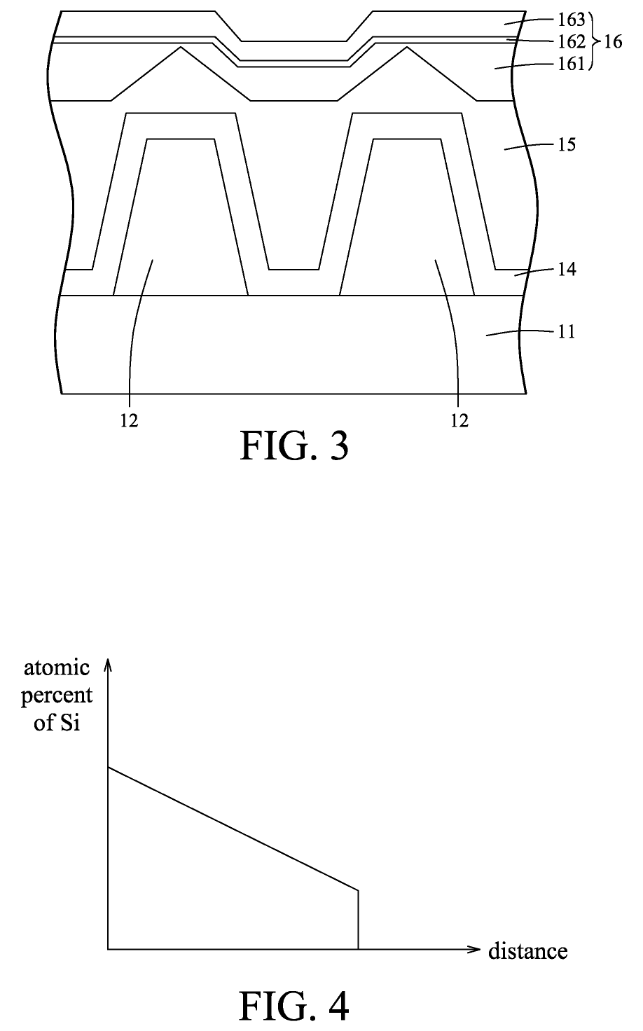

In some embodiments where the adhesion of the protection layer 14 to the conductive lines 12 is good, as shown in FIG. 3, the capping layer 13 may be omitted, and the protection layer 14 may be in contact with the top and side surfaces of each of the conductive lines 12.

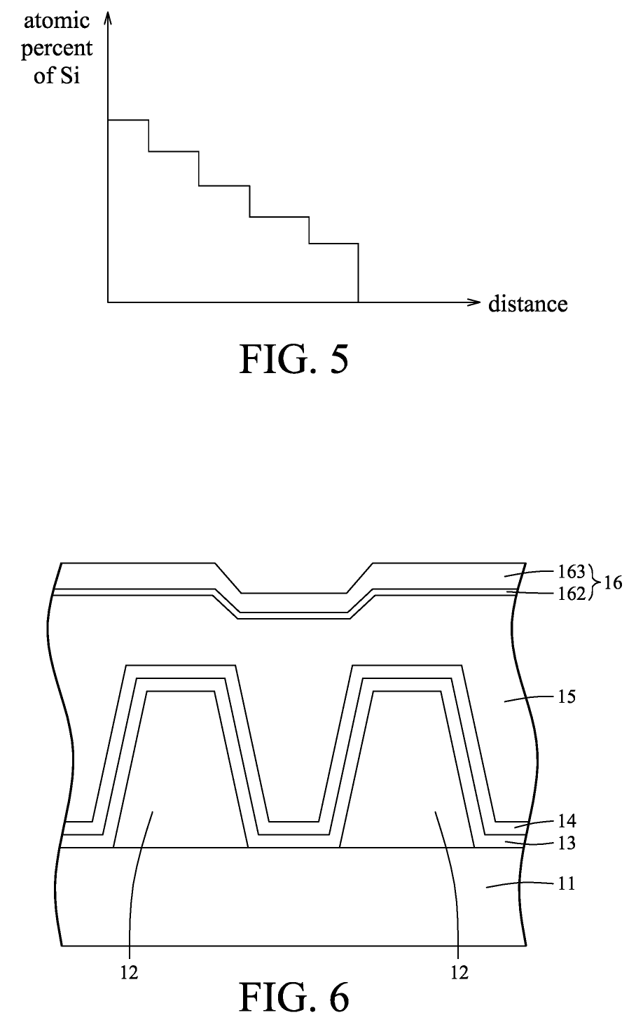

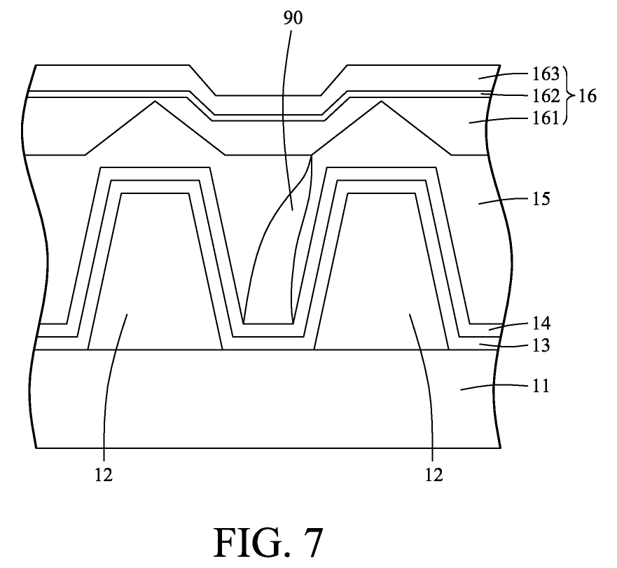

The protection layer 14 may be configured to block cracks formed in the material layers (e.g. cracks formed in the isolation layer 15) from reaching the conductive lines 12 so that the conductive lines 12 may be protected. In some embodiments, the protection layer 14 may be made of a nitride that contains silicon (Si) atoms (e.g., silicon nitride or the like). Other suitable materials are within the contemplated scope of the present disclosure. In some embodiments, an atomic percent of the silicon (Si) atoms in the protection layer 14 may decrease in a linear manner from a maximum to a minimum as a minimum distance to the capping layer 13 increases as shown in FIG. 4, thereby enhancing the adhesion of the capping layer 13 to the protection layer 14. That is, the atomic percent of the silicon (Si) atoms in the protection layer 14 may gradually decrease from its bottom surface to its top surface. In some embodiments, the bottom portion of the protection layer 14 attached to the capping layer 13 may have a first Si concentration that is greater than a second Si concentration of an upper portion of the protection layer 14 attached to the isolation layer 15. In some other embodiments, the atomic percent of the silicon (Si) atoms in the protection layer 14 may decrease in a stepwise manner as shown in FIG. 5, or in other manners. In some embodiments, the maximum of the atomic percent of the silicon (Si) atoms in the protection layer 14 (e.g. in the bottom portion of the protection layer 14) may fall within a range of from about 10% to about 30%. In some embodiments, the minimum of the atomic percent of the silicon (Si) atoms in the protection layer 14 (e.g. in the upper portion of the protection layer 14) may fall within a range of from about 0% to about 10%. In an example, the atomic percent of the silicon (Si) atoms in the protection layer 14 may decrease from the maximum of about 20% to the minimum of about 5% as the minimum distance to the capping layer 13 increases. When the maximum of the atomic percent of the silicon (Si) atoms in the protection layer 14 falls within the range of from about 10% to about 30% and the minimum of the atomic percent of the silicon (Si) atoms in the protection layer 14 falls within the range of from about 0% to about 10%, the adhesion of the capping layer 13 to the protection layer 14 may be enhanced significantly.

The isolation layer 15 may be configured to electrically isolate the conductive lines 12. In some embodiments, the isolation layer 15 may be made of an oxide that contains silicon (Si) atoms (e.g., silicon oxide or the like). Other suitable materials are within the contemplated scope of the present disclosure. In some embodiments, an atomic percent of the silicon (Si) atoms in the isolation layer 15 may be smaller than or equal to about 10%, so the isolation layer 15 may provide good electrical isolation effect. In some embodiments, the atomic percent of the silicon (Si) atoms in the isolation layer 15 may be less than the atomic percent of the silicon (Si) atoms in the capping layer 13. In some embodiments, the atomic percent of the silicon (Si) atoms in the isolation layer 15may be less than the atomic percent of the silicon (Si) atoms in the bottom portion of the protection layer 14. In some embodiments, the atomic percent of the silicon (Si) atoms in the isolation layer 15 may be greater than the atomic percent of the silicon (Si) atoms in the upper portion of the protection layer 14. In some other embodiments, the atomic percent of the silicon (Si) atoms in the isolation layer 15 may be less than the atomic percent of the silicon (Si) atoms in the upper portion of the protection layer 14.

In some embodiments, a coefficient that indicates the ability of the capping layer 13 to endure stress may fall within a range of from about -1.5 to about -0.2, a coefficient that indicates the ability of the protection layer 14 to endure stress may fall within a range of from about -1 to about 0.4, and a coefficient that indicates the ability of the isolation layer 15 to endure stress may fall within a range of from about -1.5 to about -0.5. The smaller an absolute value of the coefficient, the better the ability to endure stress. In some embodiments, the absolute value of the coefficient that indicates the ability of the protection layer 14 to endure stress may be smaller than the absolute value of the coefficient that indicates the ability of the isolation layer 15 to endure stress, so the ability of the protection layer 14 to endure stress may be better than the ability of the isolation layer 15 to endure stress. In some embodiments, a difference between the coefficient that indicates the ability of the capping layer 13 to endure stress and a coefficient that indicates the ability of the conductive lines 12 to endure stress may be smaller than a difference between the coefficient that indicates the ability of the protection layer 14 to endure stress and the coefficient that indicates the ability of the conductive lines 12 to endure stress (i.e., the capping layer 13 may be more similar to the conductive lines 12 in material characteristics than the protection layer 14), and a difference between the coefficient that indicates the ability of the capping layer 13 to endure stress and the coefficient that indicates the ability of the protection layer 14 to endure stress may be smaller than the difference between the coefficient that indicates the ability of the protection layer 14 to endure stress and the coefficient that indicates the ability of the conductive lines 12 to endure stress (i.e., the capping layer 13 may be more similar to the protection layer 14 in material characteristics than the capping layer 12), so the adhesion of the capping layer 13 to the conductive lines 12 may be better than the adhesion of the protection layer 14 to the conductive lines 12, and the adhesion of the capping layer 13 to the protection layer 14 may be better than the adhesion of the protection layer 14 to the conductive lines 12.

The passivation layer 16 may be configured to protect the elements disposed therebelow (i.e., the isolation layer 15, the protection layer 14, the capping layer 13, the conductive lines 12, the interconnect structure 11 and the substrate 10). In some embodiments, the passivation layer 16 may include a first passivation film 161, a second passivation film 162 and a third passivation film 163 that are stacked from bottom to top in the given order. In some embodiments, the first passivation film 161 may be made of an oxide that contains silicon (Si) atoms (e.g., silicon oxide or the like). Other suitable materials are within the contemplated scope of the present disclosure. In some embodiments, an atomic percent of the silicon (Si) atoms in the first passivation film 161 may be smaller than or equal to about 10%, so the first passivation film 161 may provide good electrical isolation effect. In some embodiments, the second passivation film 162 may be made of an oxide that contains silicon (Si) atoms (e.g., silicon oxide or the like). Other suitable materials are within the contemplated scope of the present disclosure. In some embodiments, an atomic percent of the silicon (Si) atoms in the second passivation film 162 may fall within a range of from about 15% to about 30%. In some embodiments, the atomic percent of the silicon (Si) atoms in first passivation film 161 may be less than the atomic percent of the silicon (Si) atoms in the second passivation film 162. In some embodiments, the third passivation film 163 may be made of a nitride that contains silicon (Si) atoms (e.g., silicon nitride or the like). Other suitable materials are within the contemplated scope of the present disclosure.

In some embodiments, a sum of a thickness (D1) of the capping layer 13, a thickness (D2) of the protection layer 14, and a thickness (D3) of the isolation layer 15 in a region between two adjacent ones of the conductive lines 12 may be greater than a height (D4) of each of the conductive lines 12 (i.e., D1 + D2 + D3 > D4), so the isolation layer 15 may function well and electrically isolate the conductive lines 12.

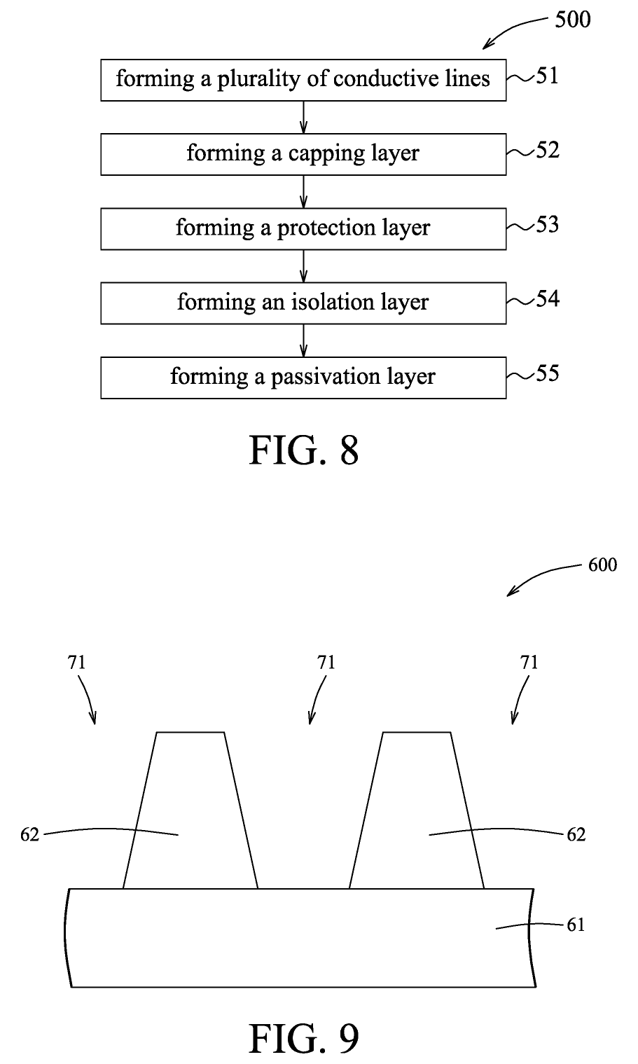

In some embodiments where the thickness (D3) of the isolation layer 15 in the region between the two adjacent ones of the conductive lines 12 is large, as shown in FIG. 6, the first passivation film 161 of the passivation layer 16 may be omitted, and the second passivation film 162 of the passivation layer 16 may be in contact with the upper surface of the isolation layer 15.

In some embodiments, the thickness (D1) of the capping layer 13 may be smaller than a half of a minimum distance (D5) between the two adjacent ones of the conductive lines 12 (i.e., D1 < 0.5 × D5), so the capping layer 13 may only partially fill the region between the two adjacent ones of the conductive lines 12, and the isolation layer 15 may provide sufficient electrical isolation effect to the conductive lines 12.

In some embodiments, the thickness (D2) of the protection layer 14 may be smaller than a half of the minimum distance (D5) between the two adjacent ones of the conductive lines 12 (i.e., D2 < 0.5 × D5), so the protection layer 14 may only partially fill the region between the two adjacent ones of the conductive lines 12, and the isolation layer 15 may provide sufficient electrical isolation effect to the conductive lines 12.

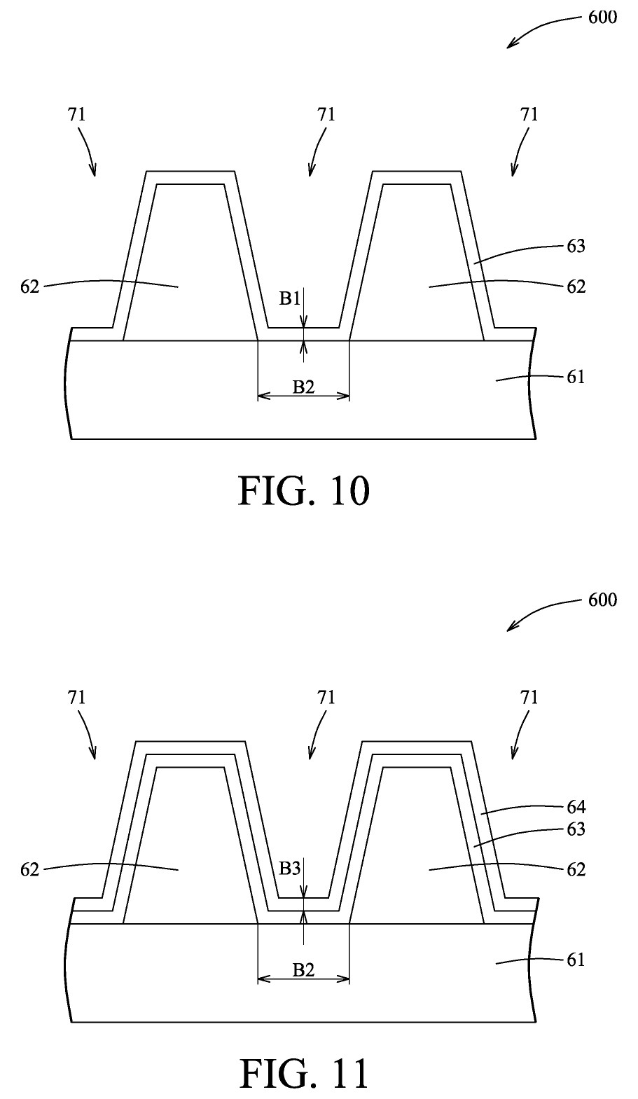

In view of the above, since the ability of the protection layer 14 to endure stress is better than the ability of the isolation layer 15 to endure stress, the protection layer 14 is more resistant to deformation than the isolation layer 15. As a consequence, the protection layer 14 would not crack even when the isolation layer 15 has already cracked (i.e., as shown in FIG. 7, the crack 90 formed in the isolation layer 15 would be blocked by the protection layer 14), thereby preventing damage to the conductive lines 12 and causing abnormal operation of the semiconductor device.

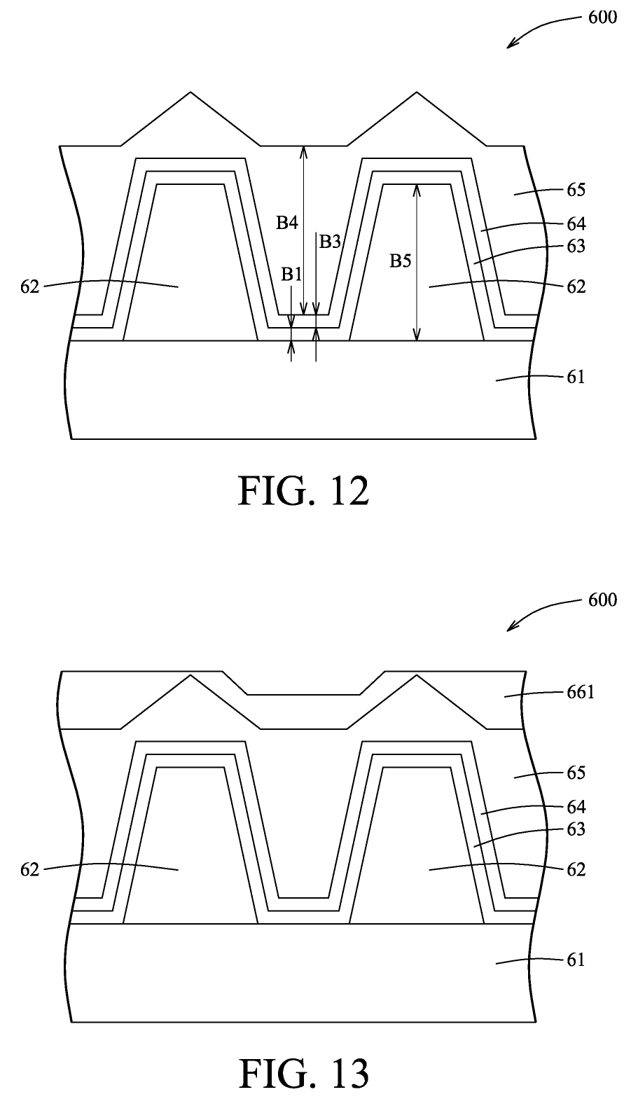

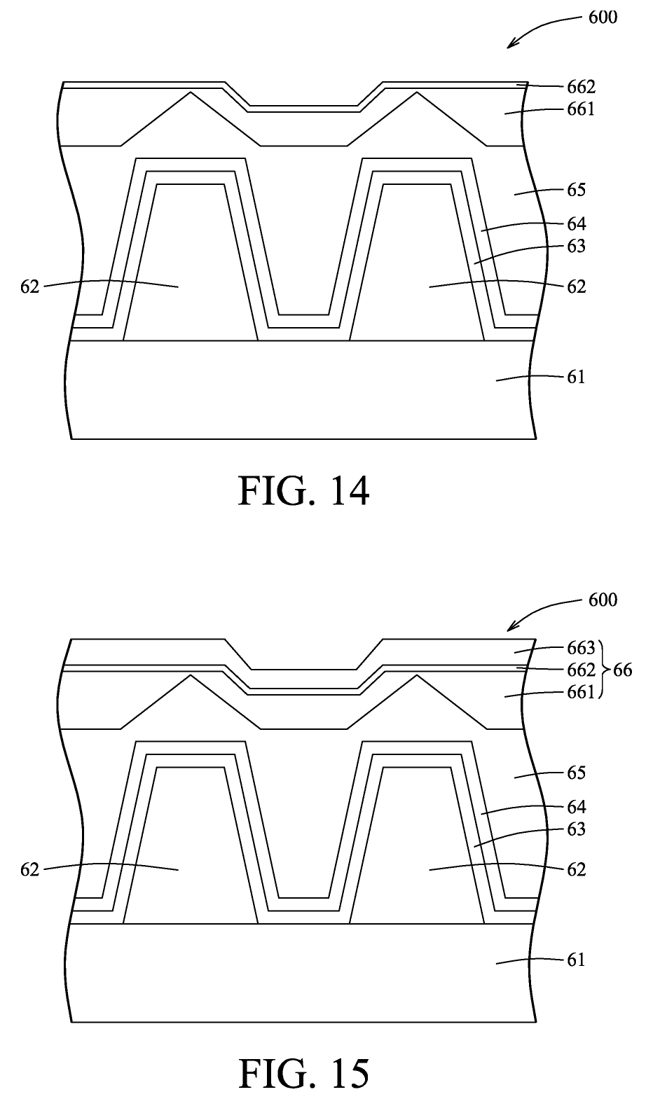

FIG. 8 is a flow chart illustrating a method 500 for manufacturing a semiconductor device in accordance with some embodiments. FIGS. 9 to 15 are schematic sectional views of semiconductor structures 600 during various stages of the method 500. The method 500 and the semiconductor structures 600 will be described together below. It should be noted that additional steps can be provided before, during or after the method 500, and some of the steps described herein may be replaced by other steps or be eliminated. Similarly, further additional features may be present in the semiconductor structures 600, and/or features present may be replaced or eliminated in additional embodiments.

Referring to FIGS. 8 and 9, the method 500 begins at step 51, where a plurality of conductive lines 62 and a plurality of recesses 71 are formed on an interconnect structure 61 disposed on a substrate (not shown). Two adjacent ones of the conductive lines 62 are spaced apart from each other by a corresponding one of the recesses 71. The substrate would serve as the substrate 10 of the semiconductor device depicted in FIGS. 1 and 2. The interconnect structure 61 would serve as the interconnect structure 11 of the semiconductor device depicted in FIGS. 1 and 2. The conductive lines 62 would serve as the conductive lines 12 of the semiconductor device depicted in FIGS. 1 and 2. In some embodiments, step 51 may be implemented as described below. First, a conductive layer for forming the conductive lines 62 is formed on the interconnect structure 61 by a suitable deposition process known in the art of semiconductor fabrication, such as physical vapor deposition (PVD), chemical vapor deposition (CVD), atomic layer deposition (ALD), plasma-enhanced chemical vapor deposition (PECVD), plasma-enhanced atomic layer deposition (PEALD), other suitable techniques, or combinations thereof. In some embodiments, the conductive layer may be made of a conductive material, such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), gold (Au), aluminum (Al), or alloys thereof. Other suitable materials are within the contemplated scope of the present disclosure. Then, the conductive layer is patterned so as to form the conductive lines 62 and the recesses 71. In some embodiments, the conductive layer may be patterned using a photolithography process and an etching process known to those skilled in the art of semiconductor fabrication. The photolithography process may include, for example, but not limited to, coating the conductive layer with a photoresist, soft-baking, exposing the photoresist through a photomask, post-exposure baking, developing the photoresist, and hard-baking, so as to form a patterned photoresist. The etching process may be implemented by etching the conductive layer through the patterned photoresist using, for example, reactive ion etching (RIE), plasma etching, deep reactive ion etching (RIE), atomic layer etching (ALE), other suitable techniques, or combinations thereof. The patterned photoresist may be removed after the etching process. Portions of the conductive layer that remain on the substrate 61 serve as the conductive lines 62.

In some embodiments, the substrate may be a semiconductor substrate, e.g., an elemental semiconductor or a compound semiconductor. An elemental semiconductor is composed of a single species of atoms, such as silicon (Si) or germanium (Ge) in column IV of the periodic table, and may be in crystalline, polycrystalline, or amorphous form. A compound semiconductor is composed of two or more elements, such as silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, gallium indium arsenide phosphide, or the like. The compound semiconductor may have a gradient feature in which the composition thereof changes from one ratio at one location to another ratio at another location in the compound semiconductor. The compound semiconductor may be formed over a silicon substrate, and the compound semiconductor may be strained. In some embodiments, the substrate may include a multilayer compound semiconductor device. Alternatively, the substrate may include a non-semiconductor material, such as glass, fused quartz, or calcium fluoride. Furthermore, in some embodiments, the substrate may be a silicon on insulator (SOI) substrate (e.g., silicon germanium on insulator (SGOI)). Generally, an SOI substrate includes a layer of a semiconductor material such as epitaxial silicon, germanium, silicon germanium, or combinations thereof. The substrate may be doped with a p-type dopant, such as boron (B), aluminum (Al), gallium (Ga), or the like, or may alternatively be doped with an n-type dopant, such as nitrogen (N), phosphorus (P), arsenic (As), or the like. In some embodiments, the substrate may include a doped epitaxial layer. Shallow trench isolation (STI) regions (not shown) may be formed in the substrate to isolate active regions, such as source or drain regions of an integrated circuit device in the substrate. In some embodiments, the integrated circuit device may include a plurality of transistors (e.g., planar field effect transistors (planar FETs), three-dimensional field effect transistors (3D FETs) such as fin field effect transistors (FinFETs), or the like). In some embodiments, the interconnect structure 61 may include a plurality of metal lines (not shown), a plurality of conductive contacts (not shown), a plurality of conductive vias (not shown), and a plurality of inter-metal dielectric layers (not shown). The metal lines, the conductive contacts and the conductive vias of the interconnect structure 61 cooperate with the conductive lines 62 to connect the transistors of the integrated circuit device in a predetermined way, so the transistors of the integrated circuit device can cooperatively perform predetermined operations. In addition, through-vias (not shown) may be formed to extend into the substrate for electrically connecting features on opposite sides of the substrate.

Referring to FIGS. 8 and 10, the method 500 then proceeds to step 52, where a capping layer 63 is conformally formed on the conductive lines 62 and the substrate 61, so as to cover top and side surfaces of each of the conductive lines 62, and portions of a top surface of the substrate 61 that are not covered by the conductive lines 62. The capping layer 63 would serve as the capping layer 13 of the semiconductor device depicted in FIGS. 1 and 2. In some embodiments, the capping layer 63 may be formed by a suitable deposition process known in the art of semiconductor fabrication, such as chemical vapor deposition (CVD), atomic layer deposition (ALD), plasma-enhanced chemical vapor deposition (PECVD), plasma-enhanced atomic layer deposition (PEALD), other suitable techniques, or combinations thereof. In some embodiments, a thickness (B1) of the capping layer 63 may be smaller than a half of a minimum distance (B2) between two adjacent ones of the conductive lines 62 (i.e., B1 < 0.5 × B2), so that the capping layer 63 only partially fills the recess 71 that separates the two adjacent ones of the conductive lines 62.

Referring to FIGS. 8 and 11, the method 500 then proceeds to step 53, where a protection layer 64 is conformally formed on the capping layer 63, so as to cover an upper surface of the capping layer 63. Adhesion of the capping layer 63 to the conductive lines 62 would be better than adhesion of the protection layer 64 to the conductive lines 62 if the capping layer 13 were to be omitted. Adhesion of the capping layer 63 to the protection layer 64 would also be better than the adhesion of the protection layer 64 to the conductive lines 62 as well. Therefore, since the capping layer 63 has good adhesion to the conductive lines 62 and to the protection layer 64, the capping layer 63 is suitably disposed between the conductive lines 62 and the protection layer 64. The protection layer 64 would serve as the protection layer 14 of the semiconductor device depicted in FIGS. 1 and 2. In some embodiments, the protection layer 64 may be formed by a suitable deposition process known in the art of semiconductor fabrication, such as chemical vapor deposition (CVD), atomic layer deposition (ALD), plasma-enhanced chemical vapor deposition (PECVD), plasma-enhanced atomic layer deposition (PEALD), other suitable techniques, or combinations thereof. In some embodiments, a thickness (B3) of the protection layer 64 may be smaller than a half of the minimum distance (B2) between the two adjacent ones of the conductive lines 62 (i.e., B3 < 0.5 × B2), so that the protection layer 64 only partially fills the recess 71 that separates the two adjacent ones of the conductive lines 62.

In some embodiments, the capping layer 63 may be made of an oxide that contains silicon (Si) atoms (e.g., silicon oxide or the like). Other suitable materials are within the contemplated scope of the present disclosure. In some embodiments, an atomic percent of the silicon (Si) atoms in the capping layer 63 may be larger than or equal to about 15%. When the atomic percent of the silicon (Si) atoms in the capping layer 63 is smaller than about 15%, the adhesion of the capping layer 63 to the conductive lines 62 and the adhesion of the capping layer 63 to the protection layer 64 may be poor. It should be noted that the atomic percent of the silicon (Si) atoms in the capping layer 63 should not be made too large in order to retain the electrical isolation effect provided by the capping layer 63.

In some embodiments, the protection layer 64 may be made of a nitride that contains silicon (Si) atoms (e.g., silicon nitride or the like). Other suitable materials are within the contemplated scope of the present disclosure. In some embodiments, an atomic percent of the silicon (Si) atoms in the protection layer 64 may decrease in a linear manner from a maximum to a minimum as a minimum distance to the capping layer 63 increases as shown in FIG. 4, thereby enhancing the adhesion of the capping layer 63 to the protection layer 64. In some other embodiments, the atomic percent of the silicon (Si) atoms in the protection layer 64 may decrease in a stepwise manner as shown in FIG. 5, or in other manners. In some embodiments, the maximum of the atomic percent of the silicon (Si) atoms in the protection layer 64 may fall within a range of from about 10% to about 30%. In some embodiments, the minimum of the atomic percent of the silicon (Si) atoms in the protection layer 64 may fall within a range of from about 0% to about 10%. In an example, the atomic percent of the silicon (Si) atoms in the protection layer 64 may decrease from the maximum of about 20% to the minimum of about 5% as the minimum distance to the capping layer 63 increases. When the maximum of the atomic percent of the silicon (Si) atoms in the protection layer 64 falls within the range of from about 10% to about 30% and the minimum of the atomic percent of the silicon (Si) atoms in the protection layer 64 falls within a range of from about 0% to about 10%, the adhesion of the capping layer 63 to the protection layer 64 may be enhanced significantly. In some embodiments, the protection layer 64 may be formed by sequentially forming a number (N) of protection films on the capping layer 63, where N≥2; each of the protection films may be made of a nitride that contains silicon (Si) atoms (e.g., silicon nitride or the like); and an atomic percent of the silicon (Si) atoms in an n^{th} one of the protection films is smaller than an atomic percent of the silicon (Si) atoms in an (n-1)^{th} one of the protection films, where 2≤n≤N, and the n^{th} one of the protection films is formed later than the (n-1)^{th} one of the protection films. As a consequence, the atomic percent of the silicon (Si) atoms in the protection layer 64 may decrease from a maximum to a minimum in a stepwise manner as the minimum distance to the capping layer 63 increases. In an example, the protection layer 64 may include five protection films (i.e., N=5); the protection films may have the same thickness; the atomic percent of the silicon (Si) atoms in a first one of the protection films (i.e., the protection film that is closest to the capping layer 63) may be about 20%; the atomic percent of the silicon (Si) atoms in a second one of the protection films may be about 16.25%; the atomic percent of the silicon (Si) atoms in a third one of the protection films may be about 12.5%; the atomic percent of the silicon (Si) atoms in a fourth one of the protection films may be about 8.75%; and the atomic percent of the silicon (Si) atoms in a fifth one of the protection films (i.e., the protection film that is furthest to the capping layer 63) may be about 5%.

Referring to FIGS. 8, 11 and 12, the method 500 then proceeds to step 54, where an isolation layer 65 is formed on the protection layer 64, so as to cover an upper surface of the protection layer 64 and fill the recesses 71. Ability of the protection layer 64 to endure stress is better than ability of the isolation layer 65 to endure stress. The isolation layer 65 would serve as the isolation layer 15 of the semiconductor device depicted in FIGS. 1 and 2. In some embodiments, the isolation layer 65 may be formed by a suitable deposition process known in the art of semiconductor fabrication, such as high density plasma chemical vapor deposition (HDPCVD), other suitable techniques, or combinations thereof. In some embodiments, the isolation layer 65 may be made of an oxide that contains silicon (Si) atoms (e.g., silicon oxide or the like). Other suitable materials are within the contemplated scope of the present disclosure. In some embodiments, an atomic percent of the silicon (Si) atoms in the isolation layer 65 may be smaller than or equal to about 10%, so the isolation layer 65 may provide good electrical isolation effect. In some embodiments, a sum of the thickness (B1) of the capping layer 63, the thickness (B3) of the protection layer 64, and a thickness (B4) of the isolation layer 65 in one of the recesses 71 may be greater than a height (B5) of each of the conductive lines 62 (i.e., B1 + B3 + B4 > B5), so the isolation layer 65 may function well and electrically isolate the conductive lines 62.

Referring to FIGS. 8 and 13 to 15, the method 500 then proceeds to step 55, where a passivation layer 66 (see FIG. 10) is formed on the isolation layer 65, so as to cover an upper surface of the isolation layer 65. The passivation layer 66 includes a first passivation film 661, a second passivation film 662 and a third passivation film 663 that are stacked from bottom to top in the given order. The first passivation film 661, the second passivation film 662 and the third passivation film 663 of the passivation layer 66 would respectively serve as the first passivation film 161, the second passivation film 162 and the third passivation film 163 of the passivation layer 16 of the semiconductor device depicted in FIGS. 1 and 2. In some embodiments, the passivation layer 66 may be formed by sequentially depositing the first passivation film 661, the second passivation film 662 and the third passivation film 663 on the isolation layer 65 in the given order. In some embodiments, the first passivation film 661 may be deposited on the isolation layer 65 using, for example, plasma-enhanced deposition such as plasma-enhanced chemical vapor deposition (PECVD) or plasma-enhanced atomic layer deposition (PEALD), other suitable techniques, or combinations thereof. In some embodiments, the first passivation film 661 may be made of an oxide that contains silicon (Si) atoms (e.g., silicon oxide or the like). Other suitable materials are within the contemplated scope of the present disclosure. In some embodiments, an atomic percent of the silicon (Si) atoms in the first passivation film 661 may be smaller than or equal to about 10%, so the first passivation film 661 may provide good electrical isolation effect. In some embodiments, the second passivation film 662 may be deposited on the first passivation film 661 using, for example, chemical vapor deposition (CVD), atomic layer deposition (ALD), plasma-enhanced chemical vapor deposition (PECVD), plasma-enhanced atomic layer deposition (PEALD), other suitable techniques, or combinations thereof. In some embodiments, the second passivation film 662 may be made of an oxide that contains silicon (Si) atoms (e.g., silicon oxide or the like). Other suitable materials are within the contemplated scope of the present disclosure. In some embodiments, an atomic percent of the silicon (Si) atoms in the second passivation film 662 may be larger than or equal to about 15%. In some embodiments, the third passivation film 663 may be deposited on the second passivation film 662 using, for example, chemical vapor deposition (CVD), atomic layer deposition (ALD), plasma-enhanced chemical vapor deposition (PECVD), plasma-enhanced atomic layer deposition (PEALD), other suitable techniques, or combinations thereof. In some embodiments, the third passivation film 663 may be made of a nitride that contains silicon (Si) atoms (e.g., silicon nitride or the like). Other suitable materials are within the contemplated scope of the present disclosure.

In accordance with some embodiments of the present disclosure, a semiconductor device includes a plurality of conductive lines, a protection layer and an isolation layer. The conductive lines are spaced apart from each other. The protection layer conformally covers the conductive lines. The isolation layer covers the protection layer. Ability of the protection layer to endure stress is better than ability of the isolation layer to endure stress.

In accordance with some embodiments of the present disclosure, a sum of a thickness of the protection layer and a thickness of the isolation layer in a region between two adjacent ones of the conductive lines is larger than a height of each of the conductive lines.

In accordance with some embodiments of the present disclosure, a thickness of the protection layer is smaller than a half of a minimum distance between two adjacent ones of the conductive lines.

In accordance with some embodiments of the present disclosure, the protection layer is made of a nitride.

In accordance with some embodiments of the present disclosure, the protection layer is made of a nitride that contains silicon atoms; and an atomic percent of the silicon atoms in the protection layer decreases as a minimum distance to the conductive lines increases.

In accordance with some embodiments of the present disclosure, a maximum of the atomic percent of the silicon atoms in the protection layer falls within a range of from 10% to 30%.

In accordance with some embodiments of the present disclosure, a minimum of the atomic percent of the silicon atoms in the protection layer falls within a range of from 0% to 10%.

In accordance with some embodiments of the present disclosure, the semiconductor device further includes a capping layer disposed between the conductive lines and the protection layer. Adhesion of the capping layer to any one of the conductive lines and the protection layer is better than adhesion of the protection layer to the conductive lines.

In accordance with some embodiments of the present disclosure, the capping layer is made of an oxide that contains silicon atoms; and an atomic percent of the silicon atoms in the capping layer is larger than or equal to 15%.

In accordance with some embodiments of the present disclosure, a semiconductor device includes a plurality of conductive lines, a capping layer, a protection layer and an isolation layer. The conductive lines are spaced apart from each other. The capping layer conformally covers the conductive lines, and is made of an oxide that contains silicon atoms. An atomic percent of the silicon atoms in the capping layer is larger than or equal to 15%. The protection layer conformally covers the capping layer, and is made of a nitride that contains silicon atoms. An atomic percent of the silicon atoms in the protection layer decreases as a minimum distance to the capping layer increases. The isolation layer covers the protection layer, and is made of an oxide.

In accordance with some embodiments of the present disclosure, a sum of a thickness of the capping layer, a thickness of the protection layer, and a thickness of the isolation layer in a region between two adjacent ones of the conductive lines is larger than a height of each of the conductive lines.

In accordance with some embodiments of the present disclosure, a thickness of the capping layer is smaller than a half of a minimum distance between two adjacent ones of the conductive lines.

In accordance with some embodiments of the present disclosure, a thickness of the protection layer is smaller than a half of a minimum distance between two adjacent ones of the conductive lines.

In accordance with some embodiments of the present disclosure, the atomic percent of the silicon atoms in the protection layer decreases in one of a linear manner and a stepwise manner.

In accordance with some embodiments of the present disclosure, a maximum of the atomic percent of the silicon atoms in the protection layer falls within a range of from 10% to 30%.

In accordance with some embodiments of the present disclosure, a minimum of the atomic percent of the silicon atoms in the protection layer falls within a range of from 0% to 10%.

In accordance with some embodiments of the present disclosure, a method for manufacturing a semiconductor device includes: forming a plurality of conductive lines; conformally forming a protection layer on the conductive lines; and forming an isolation layer on the protection layer. Ability of the protection layer to endure stress is better than ability of the isolation layer to endure stress.

In accordance with some embodiments of the present disclosure, the method further includes conformally forming a capping layer on the conductive lines. The protection layer is formed on the capping layer. Adhesion of the capping layer to any one of the conductive lines and the protection layer is better than adhesion of the protection layer to the conductive lines.

In accordance with some embodiments of the present disclosure, the protection layer contains silicon atoms; and an atomic percent of the silicon atoms in the protection layer decreases as a minimum distance to the conductive lines increases.

In accordance with some embodiments of the present disclosure, the protection layer is formed by sequentially forming a number (N) of protection films on the conductive lines, where N≥2; each of the protection films contains silicon atoms; and an atomic percent of the silicon atoms in an n^{th} one of the protection films is smaller than an atomic percent of the silicon atoms in an (n-1)^{th} one of the protection films, where 2≤n≤N, and the n^{th} one of the protection films is formed later than the (n-1)^{th} one of the protection films.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of conductive lines spaced apart from each other;
a protection layer conformally covering the conductive lines; and
an isolation layer covering the protection layer;
wherein ability of the protection layer to endure stress is better than ability of the isolation layer to endure stress.

2. The semiconductor device according to claim 1, wherein a sum of a thickness of the protection layer and a thickness of the isolation layer in a region between two adjacent ones of the conductive lines is larger than a height of each of the conductive lines.

3. The semiconductor device according to claim 1, wherein a thickness of the protection layer is smaller than a half of a minimum distance between two adjacent ones of the conductive lines.

4. The semiconductor device according to claim 1, wherein the protection layer is made of a nitride.

5. The semiconductor device according to claim 4, wherein:
the protection layer is made of a nitride that contains silicon atoms; and
an atomic percent of the silicon atoms in the protection layer decreases as a minimum distance to the conductive lines increases.

6. The semiconductor device according to claim 5, wherein a maximum of the atomic percent of the silicon atoms in the protection layer falls within a range of from 10% to 30%.

7. The semiconductor device according to claim 5, wherein a minimum of the atomic percent of the silicon atoms in the protection layer falls within a range of from 0% to 10%.

8. The semiconductor device according to claim 1, further comprising:
a capping layer disposed between the conductive lines and the protection layer;
wherein adhesion of the capping layer to any one of the conductive lines and the protection layer is better than adhesion of the protection layer to the conductive lines.

9. The semiconductor device according to claim 8, wherein:
the capping layer is made of an oxide that contains silicon atoms; and
an atomic percent of the silicon atoms in the capping layer is larger than or equal to 15%.

10. A semiconductor device comprising:
a plurality of conductive lines spaced apart from each other;
a capping layer conformally covering the conductive lines, and being made of an oxide that contains silicon atoms, an atomic percent of the silicon atoms in the capping layer being larger than or equal to 15%;
a protection layer conformally covering the capping layer, and being made of a nitride that contains silicon atoms, an atomic percent of the silicon atoms in the protection layer decreasing as a minimum distance to the capping layer increases; and
an isolation layer covering the protection layer, and being made of an oxide.

11. The semiconductor device according to claim 10, wherein a sum of a thickness of the capping layer, a thickness of the protection layer, and a thickness of the isolation layer in a region between two adjacent ones of the conductive lines is larger than a height of each of the conductive lines.

12. The semiconductor device according to claim 10, wherein a thickness of the capping layer is smaller than a half of a minimum distance between two adjacent ones of the conductive lines.

13. The semiconductor device according to claim 10, wherein a thickness of the protection layer is smaller than a half of a minimum distance between two adjacent ones of the conductive lines.

14. The semiconductor device according to claim 10, wherein:
the atomic percent of the silicon atoms in the protection layer decreases in one of a linear manner and a stepwise manner.

15. The semiconductor device according to claim 14, wherein a maximum of the atomic percent of the silicon atoms in the protection layer falls within a range of from 10% to 30%.

16. The semiconductor device according to claim 14, wherein a minimum of the atomic percent of the silicon atoms in the protection layer falls within a range of from 0% to 10%.

17. A method for manufacturing a semiconductor device, comprising:
forming a plurality of conductive lines;
conformally forming a protection layer on the conductive lines; and
forming an isolation layer on the protection layer;
wherein ability of the protection layer to endure stress is better than ability of the isolation layer to endure stress.

18. The method according to claim 17, further comprising:
conformally forming a capping layer on the conductive lines;
wherein the protection layer is formed on the capping layer; and
wherein adhesion of the capping layer to any one of the conductive lines and the protection layer is better than adhesion of the protection layer to the conductive lines.

19. The method according to claim 17, wherein:
the protection layer contains silicon atoms; and
an atomic percent of the silicon atoms in the protection layer decreases as a minimum distance to the conductive lines increases.

20. The method according to claim 17, wherein:
the protection layer is formed by sequentially forming a number (N) of protection films on the conductive lines, where N≥2;
each of the protection films contains silicon atoms; and
an atomic percent of the silicon atoms in an n^{th} one of the protection films is smaller than an atomic percent of the silicon atoms in an (n-1)^{th} one of the protection films, where 2≤n≤N, and the n^{th} one of the protection films is formed later than the (n-1)^{th} one of the protection films.
